(19) United States
(12) Patent Application Publication
(10) Pub. No.: US 2025/0196679 A1
(43) Pub. Date: Jun. 19, 2025

(54) VEHICLE CHARGING DEVICE AND VEHICLE CHARGING METHOD

(71) Applicants: Hyundai Motor Company, Seoul (KR); Kia Corporation, Seoul (KR)

(72) Inventors: Byoungcheol Jeong, Hwaseong-si (KR); Seungmin Kim, Hwaseong-si (KR)

(21) Appl. No.: 18/925,315

(22) Filed: Oct. 24, 2024

(30) Foreign Application Priority Data
Dec. 15, 2023 (KR) 10-2023-0182600

(51) Int. Cl. B60L 53/22; B60L 53/66; B60L 58/10

(52) U.S. Cl. CPC B60L 53/22; B60L 53/66; B60L 58/10; B60L 2210/44

(57) ABSTRACT

A vehicle charging device can include a junction block regulating a power flow between a charger and a battery of a vehicle, an inverter driving an electric motor by converting direct current power provided by the battery into alternating current power, and an inlet to which a connector of the charger is connected. The junction block includes a first relay connected to a first pin of the inlet to control an electrical connection between the inlet and the inverter, and the first relay is closed when an equal potential is formed between a first node defined between the first relay and the inverter and a second node defined between the first relay and the inlet.

### CROSS-REFERENCE TO RELATED APPLICATIONS

This application claims priority to and the benefit of Korean Patent Application No. 10-2023-0182600 filed in the Korean Intellectual Property Office on Dec. 15, 2023, the entire contents of which are incorporated herein by reference.

### TECHNICAL FIELD

The disclosure relates to a vehicle charging device and a vehicle charging method.

### BACKGROUND

In accordance with global trends such as the regulation of exhaust gas emissions for internal combustion engine vehicles and the introduction of eco-friendly vehicles, the production of internal combustion engine vehicles is being reduced and the transition to electric vehicles is taking place. Accordingly, the construction of infrastructure for charging electric vehicles is also actively progressing. An electric vehicle receives electric energy from the outside to charge its battery with the supplied energy, and then obtains power, which is mechanical energy, through a motor connected to wheels using the voltage charged in the battery. Therefore, it is important to construct charging infrastructure to charge rechargeable batteries of electric vehicles. To charge a vehicle, an isolation voltage may be applied from a charger for external fault diagnosis. The external fault diagnosis is performed before the charging of the vehicle is started. At this time, an excessive leakage current may occur, making it impossible to enter vehicle charging.

### SUMMARY

An embodiment of the present disclosure can provide a vehicle charging device and a vehicle charging method capable of preventing a leakage current even when an insulation voltage for external fault diagnosis is applied to charge a battery of a vehicle.

An example embodiment of the present disclosure can provide a vehicle charging device including: a junction block regulating a power flow between a charger and a battery of a vehicle; an inverter driving an electric motor by converting direct current power provided by the battery into alternating current power; and an inlet to which a connector of the charger is connected, wherein the junction block includes a first relay connected to a first pin of the inlet to control an electrical connection between the inlet and the inverter, and the first relay is closed when an equal potential is formed between a first node defined between the first relay and the inverter and a second node defined between the first relay and the inlet.

In some example embodiments, when an isolation voltage is applied from the charger before charging the vehicle, the inverter may not form an electrical connection with the second node.

In some example embodiments, when the equal potential is formed between the first node and the second node, the inverter may form an electrical connection with the second node.

In some example embodiments, the vehicle charging device may further include a second relay connected to a second pin of the inlet to control an electrical connection between the inlet and the inverter, wherein when the second relay is closed after the first relay is closed, it may be started to charge the vehicle.

In some example embodiments, the vehicle charging device may further include a vehicle charge management system (VCMS) recognizing the connection of the connector of the charger through a control pilot (CP) signal and a proximity detection (PD) signal received from the charger through the inlet.

In some example embodiments, the vehicle charging device may further include a battery management system (BMS), wherein the VCMS transmits information on the connection of the charger to the BMS through a controller area network (CAN).

In some example embodiments, the BMS may apply a voltage to the first node through pre-charge.

In some example embodiments, the BMS may control coils that open and close the first relay and the second relay, and when the equal potential is formed between the first node and the second node, the BMS may control the coils to close the first relay.

In some example embodiments, after the first relay is closed, the BMS may control the coils to close the second relay.

In some example embodiments, the inverter may include a booster that boosts a voltage for pre-charging the first node.

An example embodiment of the present disclosure can provide a vehicle charging method including: recognizing a connection of a connector of a charger through a vehicle charge management system (VCMS); pre-charging a first node defined between a first relay of a junction block and an inverter through a battery management system (BMS); determining whether an equal potential is formed between the first node and a second node defined between the first relay and an inlet; and closing the first relay through the BMS when it is determined that the equal potential is formed, wherein the junction block regulates a power flow between the charger and a battery of a vehicle.

In some example embodiments, when an isolation voltage is applied from the charger before charging the vehicle, the inverter may not form an electrical connection with the second node.

In some example embodiments, the first relay may be connected to a first pin of the inlet.

In some example embodiments, the junction block may further include a second relay connected to a second pin of the inlet to control an electrical connection between the inlet and the inverter, and the vehicle charging method may further include starting charging the vehicle when the second relay is closed after the first relay is closed.

In some example embodiments, the BMS may control coils that open and close the first relay and the second relay, and when the equal potential is formed between the first node and the second node, the BMS may control the coils to close the first relay.

In some example embodiments, after the first relay is closed, the BMS may control the coils to close the second relay.

In some example embodiments, the recognizing of the connection of the connector may include recognizing the connection of the connector of the charger through a control pilot (CP) signal and a proximity detection (PD) signal received from the charger through the inlet.

In some example embodiments, the pre-charging of the first node may include pre-charging the first node to a voltage boosted to a charging voltage through a booster.

### BRIEF DESCRIPTION OF THE DRAWINGS

FIG. 1 is a schematic diagram illustrating a vehicle charging device according to an example embodiment of the present disclosure.

FIG. 2 is a schematic diagram illustrating a vehicle charging device according to an example embodiment of the present disclosure.

FIG. 3 is a schematic diagram for explaining a phenomenon in which a leakage current occurs when an insulation voltage for external fault diagnosis is applied.

FIG. 4 is a flowchart diagram illustrating a vehicle charging method according to an example embodiment of the present disclosure.

### DETAILED DESCRIPTION OF ILLUSTRATIVE EMBODIMENTS

Hereinafter, example embodiments of the present disclosure will be described in detail with reference to the accompanying drawings, so that they can be easily carried out by those of ordinary skill in the art to which the present disclosure pertains. However, the present disclosure may be implemented in various different forms, and is not limited to the example embodiments described herein. To clearly explain the present disclosure, parts irrelevant to the description can be omitted from the drawings, and like elements can be denoted by like reference numerals throughout the specification.

Throughout the specification and the claims, when a certain part is referred to as “including” a certain component, this implies the potential for presence of other components, not precluding the presence of other components, unless explicitly stated to the contrary. Terms including ordinal numbers such as “first” and “second” may be used to describe various components, but these components are not necessarily limited by such terms. Such terms can be used merely for the purpose of distinguishing one component from another component.

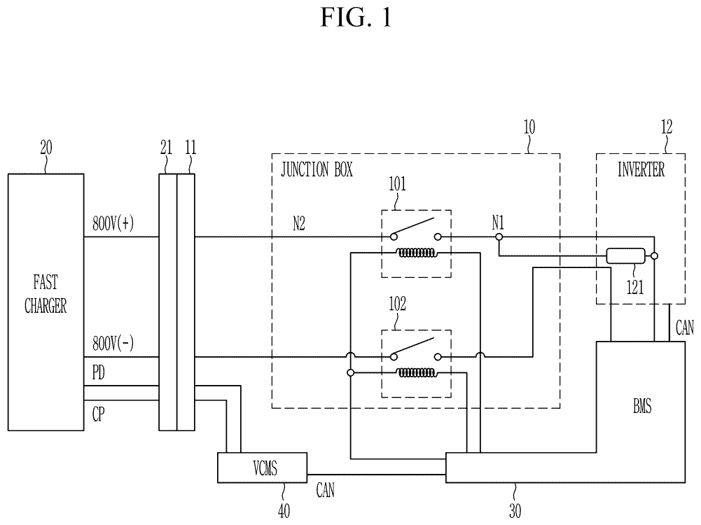

The main power sources of electric vehicles can be high-voltage batteries, which may need to be periodically inspected for insulation defects to prevent electrical leaks. For example, an insulation voltage test may be performed for an inspection by applying an insulation voltage to check whether insulation is damaged or inadequate inside an electrical system of a vehicle. The insulation voltage test may be performed by measuring an insulation resistance value while applying a high voltage higher than a general operating voltage or a rated voltage as the insulation voltage to a point to be tested in the target system. Here, if the insulation resistance value is too low, it may be assumed that an insulator is damaged or insufficient. In order to charge a vehicle, such an insulation voltage test is performed before the charging of the vehicle is started. At this time, an excessive leakage current may occur, making it impossible to enter vehicle charging. In order to solve this problem, a vehicle charging device according to an example embodiment may have a configuration as illustrated in FIG. 1.

FIG. 1 is a diagram illustrating a vehicle charging device according to an example embodiment.

Referring to FIG. 1, the vehicle charging device according to an example embodiment may include a junction block 10, an inlet 11, an inverter 12, a battery management system (BMS) 30, and a vehicle charge management system (VCMS) 40. The vehicle charging device may charge a battery of a vehicle by receiving power from a connector 21 of a charger 20.

The junction block 10 may regulate a power flow between the charger 20 and the battery of the vehicle. Alternatively, the junction block 10 may regulate a power flow between the inlet 11 and the inverter 12. The junction block 10 may include relays 101 and 102. In the drawing, it is illustrated that the relays 101 and 102 are located inside the junction block 10, but the locations of the relays 101 and 102 are not necessarily limited to the inside of the junction block 10. The relays 101 and 102 may be implemented at any locations, even not inside the junction block 10, as long as they operate between the inlet 11 and the inverter 12 to regulate a power flow therebetween.

The relay 101 may be connected to a first pin of the inlet 11 to control an electrical connection between the first pin of the inlet 11 and the inverter 12. The first pin may be a pin to which a positive voltage (e.g., 800 V (+)) is applied from the power provided by the charger 20.

The relay 102 may connected to a second pin of the inlet 11 to control an electrical connection between the second pin of the inlet 11 and the inverter 12. The second pin may be a pin to which a negative voltage (e.g., 800 V (−)) is applied from the power provided by the charger 20.

The inlet 11 may be manufactured according to a predetermined one of various standards, and the connector 21 of the charger 20 may be inserted into the inlet 11. The connector 21 may be, for example, a charging gun. The inlet 11 may receive not only power but also receive a control pilot (CP) signal and a proximity detection (PD) signal from the charger 20 through the connector 21.

The inverter 12 may drive an electric motor by converting direct current power provided by the battery into alternating current power.

A first node N1 may be defined between the relay 101 and the inverter 12. A second node N2 may be defined between the relay 101 and the inlet 11. The relay 101 may be opened during an insulation voltage test before charging the vehicle. That is, when the charger 20 applies an insulation voltage to the vehicle before charging the vehicle, the inverter 12 may not form an electrical connection with the second node N2. While the isolation voltage is applied through the first and second pins of the inlet 11, because the first node N1 and the second node N2 are electrically disconnected from each other, it can be possible to prevent an occurrence of a leakage current flowing to the inverter 12 through the first node N1.

Thereafter, in the procedure for starting the charging of the vehicle, the first relay 101 may be closed only when the first node N1 and the second node N2 form an equal potential. That is, when the equal potential is formed between the first node N1 and the second node N2, the inverter 12 may form an electrical connection with the second node N2.

In this manner, the second relay 102 may be closed after the first relay 101 is closed. Subsequently, the charging of the battery of the vehicle may be started.

The VCMS 40 may recognize a connection of the connector 21 of the charger 20 through a CP signal and a PD signal received from the charger 20 through the inlet 11. Subsequently, the VCMS 40 may transmit information on the connection of the charger 20 to the BMS 30 through a controller area network (CAN).

The BMS 30 may apply a voltage to the first node N1 through pre-charge after the insulation voltage test is completed. In particular, the inverter 12 may include a booster 121 that boosts a voltage for pre-charging the first node N1, and the BMS 30 may perform pre-charge up to the boosted voltage.

The BMS 30, which can control coils that open and close the first relay 101 and the second relay 102, may control the coils to close the first relay 101 when an equal potential is formed between the first node N1 and the second node N2. After the first relay 101 is closed, the BMS 30 may control the coils to close the second relay 102. Thereafter, the charging of the battery of the vehicle may be started.

According to the present example embodiment, when an insulation voltage, which is a high voltage, is applied through the first and second pins of the inlet 11 to perform an insulation voltage test before charging the vehicle, the relay 101 may remain opened, preventing the insulation voltage from causing an occurrence of a leakage current flowing from the second node N2 to the inverter 12 through the first node N1. Thereafter, when it is confirmed that both the first node N1 and the second node N2 form an equal potential at a charging voltage by pre-charging the first node N1 to a voltage equal to the charging voltage, the charging of the vehicle may be started by firstly closing the relay 101 and secondly closing the relay 102. As a result, an occurrence of a leakage current can be prevented, and the charging of the vehicle can be started in a safe manner.

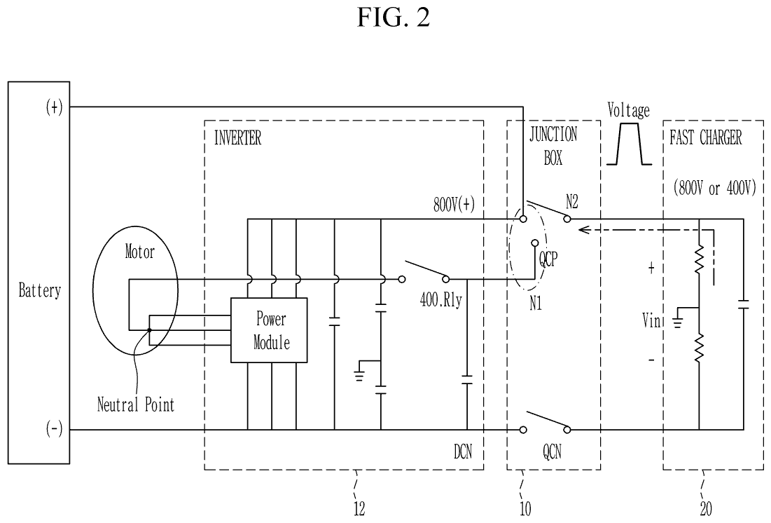

FIG. 2 is a diagram illustrating a vehicle charging device according to an example embodiment.

Referring to FIG. 2, in the vehicle charging device according to an example embodiment, an element expressed as QCP may correspond to the relay 101, and an element expressed as QCN may correspond to the relay 102. When an insulation voltage Vin, which can be a high voltage, is applied to perform an insulation voltage test before charging the vehicle, both QCP and QCN can be opened, and the first node N1 and the second node N2 can be electrically disconnected from each other. Accordingly, it can be possible to prevent the insulation voltage Vin from causing an occurrence of a leakage current flowing from the second node N2 to the inverter 12 through the first node N1.

When the insulation voltage test is completed, the first node N1 can be pre-charged to a voltage equal to the charging voltage, and the second node N2 can be brought to the charging voltage by the charger 20. When it is confirmed that both the first node N1 and the second node N2 form an equal potential at the charging voltage, the QCP can be closed first, and thereafter the QCN can be closed. Then, charging of the battery of the vehicle may be started. As a result, an occurrence of a leakage current can be prevented, and the charging of the vehicle can be started in a safe manner.

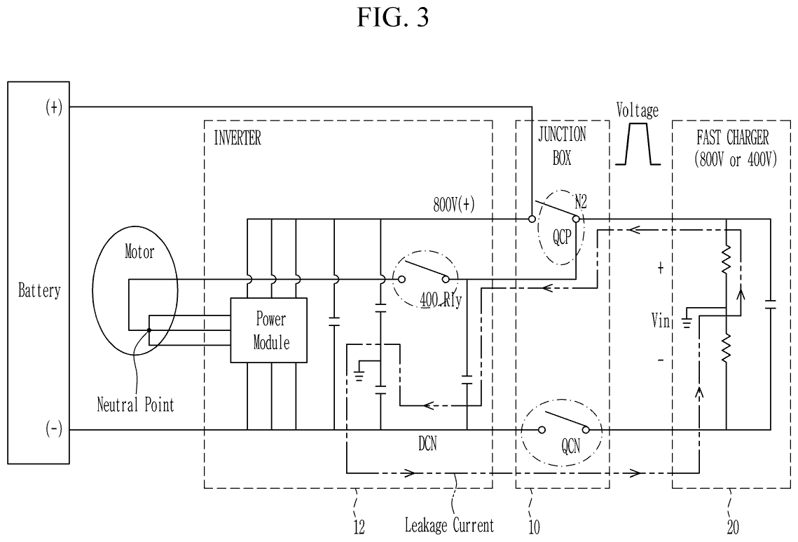

FIG. 3 is a diagram for explaining a phenomenon in which a leakage current occurs when an insulation voltage for external fault diagnosis is applied.

Referring to FIG. 3, in contrast to example embodiments, in a structure in which the inverter is directly connected to the second node N2, when an insulation voltage Vin, which is a high voltage, is applied to perform an insulation voltage test before charging the vehicle, even if both the QCP and the QCN are opened, the second node N2 may be electrically connected to the inverter. As a result, the insulation voltage Vin may cause an occurrence of a leakage current flowing from the second node N2 to the inverter 12 through the first node N1, making it impossible to enter vehicle charging if the leakage current is excessive.

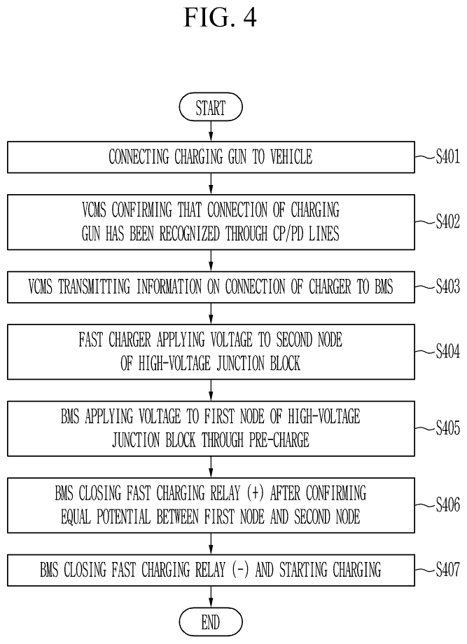

FIG. 4 is a flowchart diagram illustrating a vehicle charging method according to an example embodiment.

Referring to FIG. 4, the vehicle charging method according to an example embodiment may include: connecting a charging gun to a vehicle (operation S401); a VCMS confirming that the connection of the charging gun has been recognized through CP/PD lines (operation S402); the VCMS transmitting information on the connection of the charger to a BMS (operation S403); the fast charger applying a voltage to a second node of a high-voltage junction block (operation S404); the BMS applying a voltage to a first node of the high-voltage junction block through pre-charge (operation S405); the BMS closing a fast charging relay (+) after confirming an equal potential between the first node and the second node (operation S406); and the BMS closing a fast charging relay (−) and starting charging (operation S407).

A vehicle charging method according to an example embodiment may include: recognizing a connection of a connector of a charger through a VCMS; pre-charging a first node defined between a first relay of a junction block and an inverter through a BMS, the junction block regulating a power flow between the charger and a battery of a vehicle; determining whether an equal potential is formed between the first node and a second node defined between the first relay and an inlet; and when it is determined that the equal potential is formed, closing the first relay through the BMS.

For more detailed information about the vehicle charging method, the above explanation given with reference to FIGS. 1 to 3 can be referred to, and thus, redundant description will be omitted here.

According to the example embodiments described so far, by changing the structure inside the junction block that regulates a power flow between the charger and the battery of the vehicle, and changing the charging sequence accordingly, a leakage current can be prevented even when an insulation voltage for external fault diagnosis is applied to charge the battery of the vehicle.

Although example embodiments of the present disclosure have been described in detail above, the scopes of the present disclosure is not necessarily limited thereto, and various modifications and improvements made by those having ordinary knowledge in the art to which the present disclosure pertains using concepts of the present disclosure defined in the following claims also can fall within the scopes of the present disclosure.

What is claimed is:

1. A vehicle charging device for a vehicle that includes a battery, an electric motor, and an inverter connected to the electric motor and the battery, the vehicle charging device comprising:
an inlet configured to connect with a connector of a charger; and
a junction block configured to regulate a power flow between the charger and the battery, wherein the junction block includes a first relay connected to a first pin of the inlet to control electrical connection between the inlet and the inverter, and wherein the first relay is configured to be closed in response to an equal potential being formed between a first node defined between the first relay and the inverter and a second node defined between the first relay and the inlet.

2. The device of claim 1, wherein the device is configured so that the inverter does not form electrical connection with the second node in response to an isolation voltage being applied from the charger before charging the vehicle.

3. The device of claim 2, wherein the device is configured so that the inverter forms electrical connection with the second node in response to the equal potential being formed between the first node and the second node.

4. The device of claim 1, further comprising a second relay connected to a second pin of the inlet, wherein the second relay is configured to control electrical connection between the inlet and the inverter, and wherein the device is configured so that charging of the battery of the vehicle is started in response to the second relay being closed after the first relay is closed.

5. The device of claim 4, further comprising a vehicle charge management system (VCMS) configured to recognize connection of the connector of the charger through a control pilot (CP) signal and a proximity detection (PD) signal being received from the charger through the inlet.

6. The device of claim 5, further comprising a battery management system (BMS), wherein the VCMS is configured to transmit information on connection of the charger to the BMS through a controller area network (CAN).

7. The device of claim 6, wherein the BMS is configured to apply a first voltage to the first node through pre-charge.

8. The device of claim 7, wherein the BMS is configured to control coils that open and close the first relay and the second relay, and wherein the BMS is configured to control the coils to close the first relay in response to the equal potential being formed between the first node and the second node.

9. The device of claim 8, wherein the BMS is configured to control the coils to close the second relay after the first relay is closed.

10. The device of claim 9, wherein the inverter includes a booster configured to boost the first voltage for pre-charging the first node.

11. A method for charging a battery of a vehicle that includes the battery, a vehicle charge management system (VCMS), a junction block, an inverter, and battery management system (BMS), the method comprising:
recognizing connection of a connector of a charger by the VCMS;
pre-charging a first node by the BMS, wherein the first node is defined between a first relay of the junction block and the inverter;
determining whether an equal potential is formed between the first node and a second node defined between the first relay and an inlet; and
closing the first relay by the BMS in response to determining that the equal potential is formed, wherein the junction block regulates a power flow between the charger and the battery.

12. The method of claim 11, wherein, in response to an isolation voltage being applied from the charger before charging the battery, the inverter does not form electrical connection with the second node.

13. The method of claim 11, wherein the first relay is connected to a first pin of the inlet.

14. The method of claim 13, wherein the junction block further comprises a second relay connected to a second pin of the inlet to control electrical connection between the inlet and the inverter, and wherein the method further comprises starting charging of the battery in response to the second relay being closed after the first relay is closed.

15. The method of claim 14, further comprising:
controlling coils that open and close the first relay and the second relay by the BMS; and
closing the first relay under control by the BMS in response to the equal potential being formed between the first node and the second node.

16. The method of claim 15, wherein the method further comprises closing the second relay under control by the BMS after the first relay is closed.

17. The method of claim 11, wherein the recognizing connection of the connector comprises recognizing connection of the connector of the charger through a control pilot (CP) signal and a proximity detection (PD) signal received from the charger through the inlet.

18. The method of claim 11, wherein the pre-charging of the first node comprises pre-charging the first node to a voltage boosted to a charging voltage through a booster.

19. A method for charging a battery of a vehicle, the method comprising:
opening a first relay and a second relay, wherein a first node of the first relay is electrically coupled to an inverter of the vehicle, wherein a second node of the first relay is electrically coupled to a first pin of a charging inlet for the vehicle, wherein a third node of the second relay is electrically coupled to the inverter, and wherein a fourth node of the second relay is electrically coupled to a second pin of the charging inlet;
connecting a charger to the charging inlet;
applying an isolation voltage from the charger across the first pin and the second pin of the charging inlet while the first relay and the second relay remain open such that the inverter is electrically isolated from the isolation voltage by the first relay and the second relay being open;
closing the first relay in response to forming a pre-charge voltage across the first node and the third node that is equal to the isolation voltage; and
closing the second relay and starting charging of the battery after the first relay is closed.

20. The method of claim 19, further comprising:
recognizing connection the charger to the charging inlet by a vehicle charge management system (VCMS) of the vehicle;
pre-charging by a battery management system (BMS) of the vehicle for the forming of the pre-charge voltage;
determining whether an equal potential is formed between the first node and the second node;
closing the first relay by the BMS in response to determining that the equal potential is formed; and
regulating a power flow between the charger and the battery by a junction block of the vehicle during the charging of the battery.
